(19) United States
(12) Patent Application Publication
(10) Pub. No.: US 2003/0161124 A1
(43) Pub. Date: Aug. 28, 2003

(54) Wiring-design system for wiring-board for area-input/output-type semiconductor chip

(75) Inventor: Syuuichi Kariyazaki, Kanagawa (JP)

Correspondence Address: FOLEY AND LARDNER, SUITE 500, 3000 K STREET NW, WASHINGTON, DC, 20007, US

(73) Assignee: NEC Electronics Corporation

(21) Appl. No.: 10/372,403

(22) Filed: Feb. 25, 2003

(30) Foreign Application Priority Data
Feb. 26, 2002 (JP) 2002-049088

(51) Int. Cl. H05K 7/10; H05K 7/12

(52) U.S. Cl. 361/767

(57) ABSTRACT

In a wiring-design system for designing a wiring-arrangement for a wiring-board on which an area-input/output type semiconductor chip is mounted, a display unit displays a lattice representing an array of pads to be provided on a chip surface of the semiconductor chip. A first layout design system defines and arranges various IO blocks on the lattice to thereby design a first layout of IO blocks thereon. A check system checks whether or not the first layout of IO blocks is properly performed in accordance with a layout rule. When the check system confirms that the first layout of IO blocks is properly performed, a second layout design system designs a second layout of IO block to be provided on the wiring-board, based on the first layout of IO blocks on the lattice. A wiring-arrangement is designed in the wiring-board concerning the second layout of IO blocks.

### BACKGROUND OF THE INVENTION

1. Field of the Invention

The present invention relates to a wiring-design system for designing a wiring-arrangement for a wiring-board on which an area-input/output (area-IO) type semiconductor chip is mounted, and more particularly to an improvement of such a wiring-design system.

2. Description of the Related Art

The area-IO type semiconductor chip is frequently constituted as a flip-chip (FC) type semiconductor chip, which has been developed to meet the demands of higher performance, smaller and lighter size, and higher speed for a piece of electronic equipment. Generally, the FC type semiconductor chip has a plurality of electrodes or pads arranged on a chip surface thereof, and a plurality of metal bumps adhered to the pads. Each of the metal bumps may be formed of solder or gold, and serves as an electrode terminal or lead.

Also, the FC type semiconductor chip is frequently used in an electronic package, which is called a flip-chip type BGA (ball grid array) package. In the FC type BGA package, the FC type semiconductor chip (bare chip) is mounted on a wiring-board, which is called a package board or an interposer, such that the respective metal bumps of the FC type semiconductor are correspondingly contacted with and adhered to pads formed and arranged on an upper surface of the wiring-board. In short, the wiring-board is provided with substantially the same arrangement of pads as the FC type semiconductor chip, such that the respective pads of the FC type semiconductor chip are electrically connected to the pads of the wiring-board through the intermediary of the metal bumps.

Note, a space between the FC type semiconductor chip and the wiring-board is filled with a suitable thermosetting resin, and otherwise the FC type semiconductor per se is sealed with a molded resin on the wiring-board.

In the FC type BGA package, the wiring-board has a plurality of electrodes or pads arranged on a lower or bottom surface thereof, and a plurality of solder balls adhered to the pads, with the solder balls forming the ball grid array (BGA). Also, the wiring-board includes a ground layer, an electric power source layer, and a signal layer, and each of the solder balls is electrically connected to one of the ground, power source and signal layers. On the other hand, each of the pads of the mounted FC type semiconductor chip is electrically connected to one of the ground, power source and signal layers of the wiring-board.

Thus, the FC type BGA package is mounted as one of various electronic products on a motherboard for a piece of electronic equipment, such that the respective solder balls of the package are correspondingly contacted with and adhered to pads formed and arranged on the motherboard.

As is well known, the FC type semiconductor chip features a considerably-high integration, and thus a wiring-arrangement of the wiring-board is very complex. Thus, it is very troublesome to design the wiring-arrangement of the wiring-board. In order to facilitate the design of the wiring-arrangement of the wiring-board, the area-IO type semiconductor chip has been developed.

In the area-IO type semiconductor chip, various input/output (IO) blocks are defined on the arrangement of pads of the semiconductor chip in accordance with various circuit patterns formed in the chip surface thereof, and each IO block forms a group of pads arranged in a matrix manner. In each group, at least one pad in each group serves as a ground pad to be connected to the ground layer of the wiring-board, at least another pad serves as an electric power source pad to be connected to the power source layer of the wiring-board, and each of the remaining pads serves as a signal pad to be connected to the signal layer of the wiring-board.

Conventionally, the design of the semiconductor chip and the design of the wiring-arrangement of the wiring-board are individually performed. Namely, the design of the semiconductor chip and the design of the wiring-arrangement are independent from each other. Accordingly, when it is impossible to design the wiring-arrangement for the wiring-board based on the design of the semiconductor chip, it is necessary to revise or modify the design of the semiconductor chip, and otherwise it has to be tried again.

Various wiring-design system have already been proposed to automatically design a wiring-arrangement of a wiring-board on which a semiconductor chip is mounted, as disclosed in, for example, Japanese Laid-Open Patent Publications (KOKAI) No. HEI-06-045443, HEI-09-069568, and 2001-015637.

The Publication No. HEI-06-045443 aims at making wiring congestion uniform in an automatic wiring process of a semiconductor integrated circuit, and further at limiting a number of nets and net passing positions in a route determining process using an optimizing algorithm to reduce a processing time.

The Publication No. HEI-09-069568 aims at easily automating an ASIC (Application Specific Integrated Circuit) design in flip-chip configuration by increasing a degree of freedom of an arrangement of input/output buffers without affecting a basic algorithm of an automatic arrangement wiring tool used for a conventional ASIC design.

The Publication No. 2001-015637 aims at producing an optimum wiring candidate by automatically selecting a combination for connecting a plurality of solder ball connection pads and a plurality of wire bond pads.

Nevertheless, these publications fail to disclose that the design of a wiring-arrangement for a wiring-board is performed based on a design of a semiconductor chip. Namely, in all cases, the wiring-arrangement for the wiring-board is designed without taking the design of an semiconductor chip into consideration. Thus, when the wiring-arrangement for the wiring-board cannot be designed based on the design of the semiconductor chip, the design of the semiconductor chip must be revised or modified, or otherwise it must be tried again.

### SUMMARY OF THE INVENTION

Therefore, an object of the present invention is to provide a wiring-design system, in which a design of a wiring-arrangement for a wiring-board can be securely and properly performed without any revision or modification in a design of an area-input/output type semiconductor chip.

In accordance with the present invention, there is provided a wiring-design system for designing a wiring-arrangement for a wiring-board on which an area-input/output type semiconductor chip is mounted. In this wiring-design system, a display unit displays a lattice representing an array of pads to be provided on a chip surface of the semiconductor chip, and a first layout design system defines and arranges various IO blocks on the lattice to thereby design a first layout of IO blocks thereon. A check system checks whether or not the first layout of IO blocks is properly performed in accordance with a previously-prepared layout rule, and a second layout design system that designs a second layout of IO block to be provided on the wiring-board, based on the first layout of IO blocks on the lattice when it is confirmed by the check system that the first layout of IO blocks is properly performed. A wiring-arrangement production system produces a wiring-arrangement of the wiring-board with respect to the second layout of IO blocks.

Each of the IO blocks is composed of ground pads to be connected to a ground layer of the wiring-board, electric power pads to be connected an electric power layer of the wiring board, and signal pads to be connected to a signal layer of the wiring-board.

The second layout design system may include a line-passage-area-definition system for defining line-passage areas with respect to each of the IO blocks on the wiring-board, and wiring-lines drawn out from the signal pads of each IO block passing through a corresponding line passage area.

The second layout design system may include a geometrical-quadrilateral production system for producing a geometrical quadrilateral on the second layout of IO blocks such that the sides of the geometrical quadrilateral are tangential to outer sides of the outermost IO blocks, and the geometrical-quadrilateral production system is cooperated with the line-passage-area-definition system such that each line-passage area is defined and produced on and along a corresponding side of the geometrical quadrilateral.

The geometrical-quadrilateral production system may produce another geometrical quadrilateral when there are remaining IO blocks provided inside the outermost IO, the production of the other geometrical quadrilateral is performed such that the sides of the other geometrical quadrilateral are tangential to outer sides of the remaining IO blocks, and the geometrical-quadrilateral production system is cooperated with the line-passage-area-definition system such that each line-passage area is defined and produced on and along a corresponding side of the other geometrical quadrilateral.

The signal layer of the wiring-board may be formed as a multi-layer structure including signal layers, a number of which corresponds to a number of the geometrical quadrilaterals, and the wiring-lines, passing through the line-passage area involved with the outermost geometrical quadrilateral are connected to the uppermost signal layer.

The previously-prepared layout rule may comprise at least two types of layout rules, and one of the at least two types of layout rules is severer than the other type of layout rule. The check system selects one of the at least two types of layout rules in accordance with design requirements of the wiring-arrangement for the wiring-board. Also, the check system may include a determination system for determining whether two adjacent IO blocks are arranged in any one of corner areas of the lattice, and may checks whether the two adjacent IO blocks are properly arranged in accordance with the one type of layout rules.

### BRIEF DESCRIPTION OF THE DRAWINGS

The above objects and other objects will be more clearly understood from the description set forth below, with reference to the accompanying drawings, wherein:

FIG. 1 is a conceptual and schematic view showing a process for assembling a flip-chip type BGA (ball grid array) package having a wiring-board, a wiring-arrangement of which is designed by a wiring-design system according to the present invention;

FIG. 2 is a block diagram of a wiring-design system for designing the wiring-arrangement for the wiring-board according to the present invention;

FIG. 3 is a view showing a part of a lattice for performing a wiring-design for the wiring-board, displayed on an initial screen of a display unit shown in FIG. 2;

FIG. 4 is a conceptual view showing an IO block library defined in a hard disk shown in FIG. 2;

FIG. 5 is a view showing another part of the lattice on which an IO block is defined and arranged;

FIG. 6 is a view showing the same part of the lattice as FIG. 5, with the IO block being rotated clockwise by an angle of 90 degrees;

FIG. 7 is a conceptual view showing a general layout rule, stored as a two-dimensional table in the hard disk, for a layout of IO blocks to be arranged on the lattice;

FIG. 8 is a conceptual view showing a special layout rule, stored as a two-dimensional table in the hard disk, for a layout of to blocks to be arranged on the lattice;

FIG. 9 is a view showing a whole of the lattice displayed on the screen of the display unit;

FIG. 10 is a view of a completed proper layout of IO blocks arranged on the lattice;

FIG. 11 is a view of a layout of IO blocks on the wiring-board, which is obtained from the completed layout of IO blocks on the lattice;

FIG. 12 is a view, similar to FIG. 11, on which a line-passage area is defined with respect of each IO block;

FIG. 13 is a partially-enlarged view of FIG. 12, representatively showing wiring-lines drawn out of S-pads of each IO block to a corresponding line-passage area;

FIG. 14 is a partially-cutaway elevation view showing an interior structure of the wiring-board;

FIG. 15 is a flowchart of a main wiring-design routine which is executed in a system control unit shown in FIG. 2;

FIG. 16 is a flowchart of a primary design routine executed as a subroutine in the main wiring-design routine of FIG. 15;

FIG. 17 is a flowchart of a layout-check routine executed as a subroutine in the primary design routine of FIG. 16;

FIGS. 18A to 18D are views showing various relative positional relationships between two IO blocks, to assist the explanation of the flowchart of FIG. 17; and

FIG. 19 is a flowchart of the quadrilateral-production routine executed as a subroutine in the primary design routine of FIG. 16.

### DESCRIPTION OF THE PREFERRED EMBODIMENTS

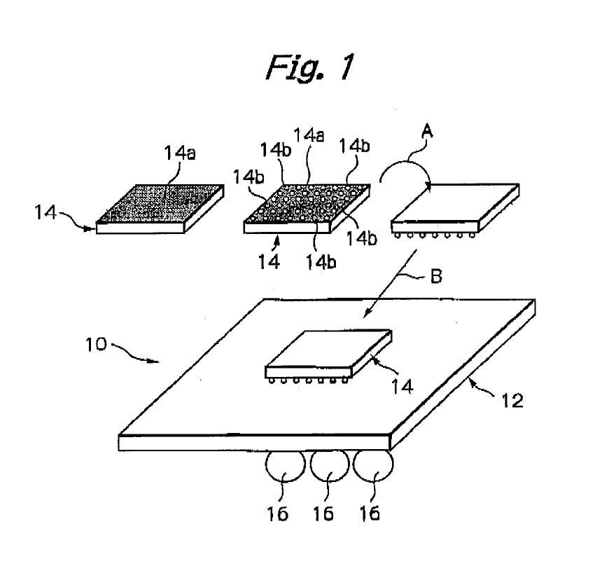

Referring to FIG. 1, a process for assembling a flip-chip type BGA (ball grid array) package, generally indicated by reference 10, is conceptually and schematically shown. The flip-chip type BGA package 10 comprises a wiring-board 12, a flip-chip (FC) type transistor chip 14 securely mounted on an upper surface of the wiring-board 12, and a ball grid array of solder balls 16 provided on a lower or bottom surface of the wiring-board 12. The flip-chip type transistor chip 14 is constituted as an area-input/output (area-IO) type semiconductor chip.

Note, in FIG. 1, although only three solder balls 16 are illustrated by way of example, in reality, the wiring-board 12 has a plurality of solder balls 16 which are uniformly arranged on the bottom surface of the wiring-board 12, with the solder balls 16 forming the ball grid array (BGA).

For example, the FC type transistor chip 14 may be derived from a gate-array type semiconductor chip. Various circuit patterns are formed on a chip surface 14a of the transistor chip 14 to thereby produce a plurality of logic circuit elements in the chip surface 14a. Then, a plurality of electrodes or pads is formed and arranged on the chip surface 14a, and respective metal (solder or gold) bumps 14b are adhered to the pads on the chip surface 14a, as shown in FIG. 1.

Subsequently, the transistor chip 14 is flipped over, as indicated by an arrow A in FIG. 1, and is put in place on the upper surface of the wiring-board 12, as indicated by an arrow B in FIG. 1, such that the respective metal bumps 14b are correspondingly contacted with pads formed and arranged on the upper surface of the wiring-board 12.

For example, when the metal bumps 14b are made of solder, these solder bumps 14b are exposed to hot air so as to be thermally fused, whereby each solder bump is soldered to both the corresponding pads. In short, the wiring-board 12 has substantially the same arrangement of pads as the semiconductor chip 14, and thus the respective pads of the semiconductor chip 14 are electrically connected to the pads of the wiring-board 12 through the intermediary of the metal bumps 14b.

Thereafter, a space between the semiconductor chip 14 and the wiring-board 12 is filled with a suitable thermosetting resin, and otherwise the semiconductor 14 per se is sealed with a molded resin on the wiring-board 12, thereby producing the PC type BGA package 10.

The wiring-board 12 also has a plurality of pads arranged on the bottom surface thereof, and the respective solder balls 16 are adhered to the pads. The wiring-board 12 has a wiring-arrangement for establishing electrical connections between the metal bumps 14b of the semiconductor chip 14 and the solder balls 16 of the wiring-board 12. The wiring-arrangement for the wiring-board 12 is constituted from a network of wiring-lines, and each of the wiring-lines may be formed of a suitable metal, such as aluminum.

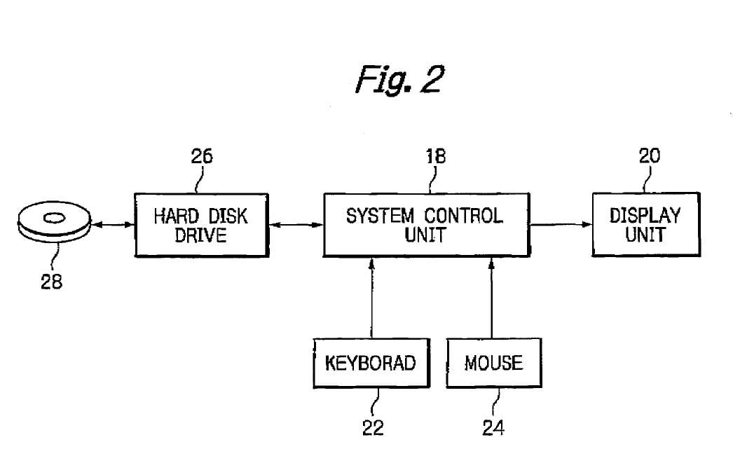

With reference to FIG. 2, a wiring-design system for designing the wiring-arrangement for the wiring-board 12 is shown. The wiring-design system comprises a system control unit 18 which contains a microcomputer comprising a central processing unit (CPU), a read-only memory (ROM) for storing programs and constants, a random-access memory (RAM) for storing temporary data, and an input/output (I/O) interface circuit.

The wiring-design system also comprises a display unit 20 (CRT, LCD) for displaying a wiring diagram on a design, and various command items, and a keyboard 22 for inputting various commands and data, necessary for the design of the wiring-arrangement, to the system control unit 18 though the I/O interface circuit thereof. The wiring-design system may be provided with a mouse 24 for inputting a command to the system control unit 18 by clicking the mouse 24 on any one of the command items displayed on the display unit 20.

The wiring-design system further comprises a hard disk drive 26 for driving a hard disk 28 in which a wiring-design program, other programs, and various tables and so on are stored. The system control unit 18 writes the programs and the various data in the hard disk 28 through the hard disk drive 26, and also reads the various data from the hard disk 28 through the hard disk drive 26.

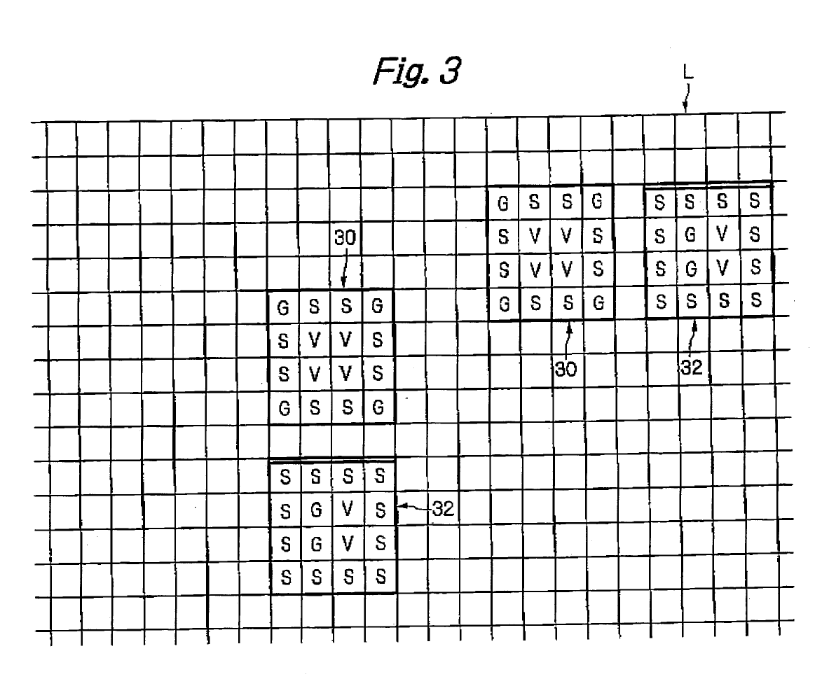

With reference to FIG. 3, a part of an initial screen of the display unit 20 for performing a wiring-design of the wiring board 12 is shown by way of example. At an initial wiring-design stage, the display unit 20 displays a lattice L including a plurality of small squares, which represent the arrangement of pads provided on the chip surface 14a of the FC type semiconductor chip 14. Namely, each of the small squares represents a pad formed on the chip surface 14a, and a distance between the centers of the two adjacent small squares is equivalent to an array pitch of the pads arranged on the chip surface 14a.

As already stated above, the transistor chip 14 is constituted as an area-input/output type semiconductor chip. Thus, as shown in FIG. 3 by way of example, input/output (IO) blocks 30 and 32 of various types are defined and arranged on the lattice L in accordance with various circuit patterns formed in the chip surface 14a. In this example, each IO block (30, 32) forms a group of sixteen pads arranged in a 4×4 matrix manner.

In the IO block 30, two of the sixteen pads are represented by reference G, and each G-pad is connected to a ground layer included in the wiring-board 12. Two of the other fourteen pads are represented by reference V, and each V-pad is connected to a power source layer included in the wiring-board 12, and the remaining twelve pads are represented by references S, and each S-pad is connected to a signal layer included in the wiring-board 12. Similarly, in the IO block 32, four G-pads are connected to the ground layer included in the wiring-board 12, four V-pads are connected to the electric power source layer included in the wiring-board 12, and the remaining eight pads S-pads are connected to the signal layer included in the wiring-board 12.

In reality, the small squares representing the G-pads, V-pads, and S-pads are colorfully displayed on the screen of the display unit 20 to thereby distinguish them from each other. For example, the respective squares representing the G-pad, V-pad, and S-pad are displayed with black, red, and green.

In this embodiment, the respective IO blocks 30 and 32 are called TYPE-A and TYPE-B, and IO blocks of other types,may be further used, if necessary. For example, for the sake of convenience, the other types of IO block are represented by TYPE-C, TYPE-D. and TYPE-E. Although each IO block (30, 32) is formed from the sixteen pads, it may formed from plural pads arranged in an m×n matrix manner (m, n=integer). Of course, this is true for each of TYPE-C, TYPE-D, and TYPE-E.

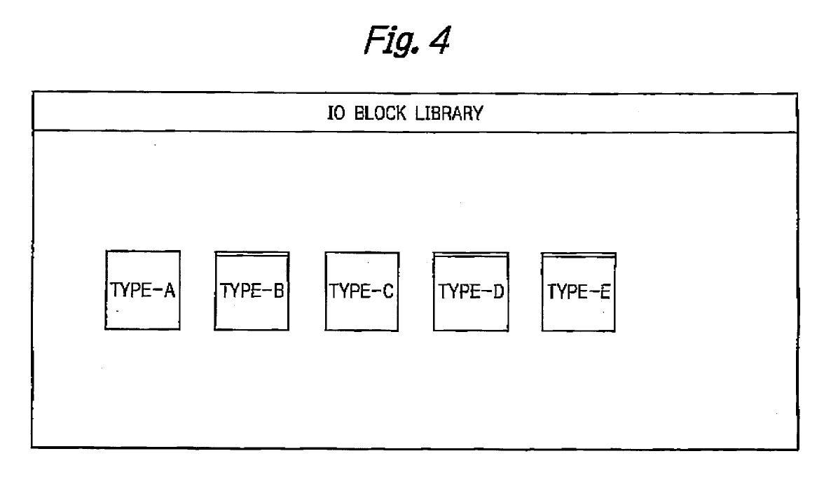

The IO blocks of all types are previously prepared and stored in an IO block library defined in the hard disk 28. Referring to FIG. 4, the IO block library, defined in the hard disk 28) is conceptually shown. When a new type of IO block is necessitated, it is prepared and added to the IO block library, thereby enriching the IO block library.

On the screen of the display unit 20, an icon for representing the IO block library is displayed. When the icon is designated by operating either the keyboard 22 or the mouse 24, a window is opened on the screen of the display unit 20 to display respective icons representing the various types of IO blocks (TYPE-A, TYPE-B, TYPE-C, TYPE-D, and TYPE-E). The definition of an IO block on the lattice L is performed by dragging a corresponding icon from the window to a given position on the lattice L. For example, in order to define each IO block 30 on the lattice L, as shown in FIG. 3, it is necessary to drag the icon, representing TYPE-A, from the window to a corresponding position by manipulating the mouse 24.

Among the various types of IO block, there is a type of IO block exhibiting a directivity. For example, the IO block 30 of TYPE-A exhibits no directivity, because the G-pads, V-pads, and S-pads are symmetrically arranged with respect to the center of the IO block 30. On the contrary, the IO block 32 of TYPE-B exhibits a directivity, because the G-pads, V-pads, and S-pads are not symmetrically arranged with respect to the center of the IO block 30. In the IO block 32, it is previously determined what side of the IO block 32 is used to draw out wiring-lines from the S-pads, and this side is featured by a double-line, as shown in FIG. 3. Note, as is apparent from FIG. 4, the IO block of TYPE-C exhibits no directivity, but the IO blocks of TYPE-D and TYPE-E exhibit a directivity.

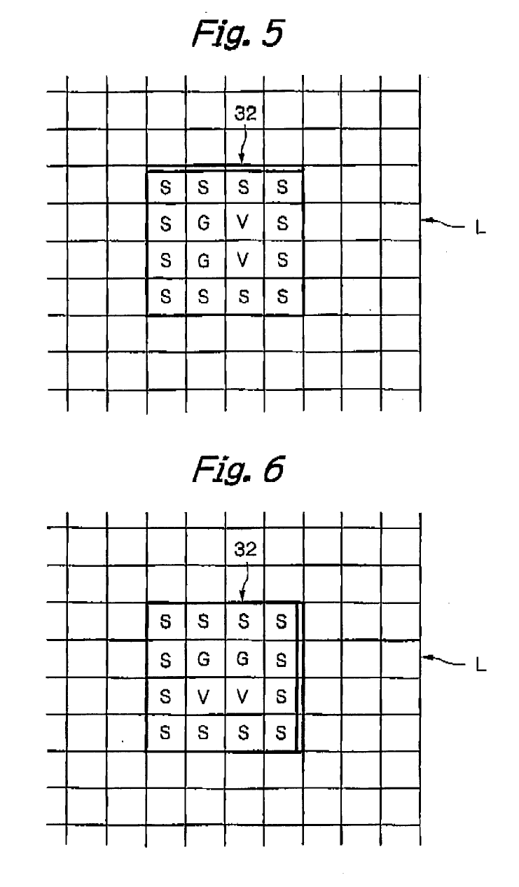

For example, when an IO block 32 is defined and arranged such that the double-line side thereof As directed to the left side of the lattice L, the icon, representing TYPE-B, is dragged from the window to a given position, as shown in FIG. 5, and then the IO block 32 is rotated clockwise by an angle of 90 degrees with operating the mouse 24, as shown in FIG. 6. Of course, by rotating the IO block 32 clockwise by an angle of 180 degrees, the double-line side of the IO block 32 can be Is directed to the lower side of the lattice L, and, by rotating the IO block 32 clockwise by an angle of 270 degrees, the double-line side of the IO block 32 can be directed to the right side of the lattice L.

In short, when all IO blocks of various types are defined and arranged on the lattice L in accordance with the circuit patterns formed in the chip surface 14a of the semiconductor chip 14, a layout of IO blocks on the chip surface 14a is finished.

According to the present invention, after the layout of IO block on the chip surface 14a is finished, it is confirmed whether the layout of IO blocks is properly and correctly performed, as explained in detail hereinafter. To this end, a general layout rule for the layout of IO blocks on the chip surface 14a is previously prepared on the basis of design requirements of the wiring-arrangement for the wiring-board 12, and is stored as a two-dimensional table in the hard disk 28.

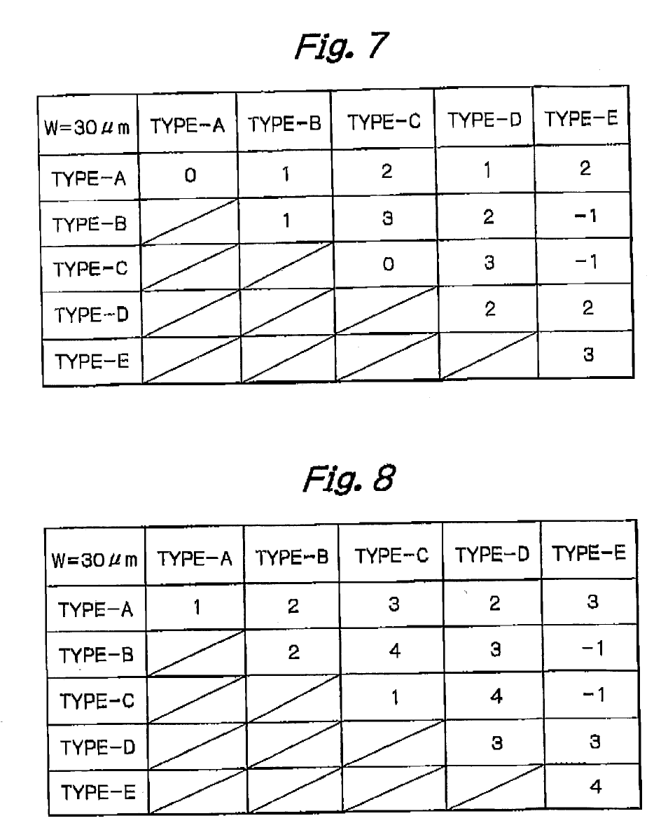

With reference to FIG. 7, the general layout rule is conceptually shown by way of example. In this example, a setting of 30 μm is given to a width W of a wiring-line to be drawn out from each S-signal pad, and thus the layout of IO blocks must be performed in accordance with the general layout rule of FIG. 7, before the wiring-arrangement can be properly designed in the wiring-board 12.

In particular, in the general layout rule of FIG. 7, a distance by which two adjacent IO blocks should be spaced apart from each other when being arranged on the lattice L, is numerically represented as a unit of the array pitch of the pads. For example, when the IO block (30) of TYPE-A and the IO block (32) of TYPE-B are arranged to be adjacent to each other, these IO blocks 30 and 32 should be spaced away from each other by at least a distance of one array pitch, before respective wiring-lines can be properly drawn out from the S-pads of each IO block (30, 32) without being subjected to interference.

Also, as is apparent from FIG. 7, two adjacent IO blocks 30 of TYPE-A can be arranged so as to be close to each other without any space therebetween, whereas two adjacent IO blocks 32 of TYPE-B must be arranged so as to be spaced away from each other by at least a distance of one array pitch. Further, for example, when an IO block of TYPE-C and an IO block of TYPE-D are arranged to be adjacent to each other, these IO blocks must be spaced away from each other by a distance of three array pitches, as shown in FIG. 7. In short, in the general layout rule of FIG. 7, each of the numerals represents a minimum permissible distance, by which two adjacent IO blocks should be spaced away from each other when being arranged on the lattice L.

Note, in the general layout rule of FIG. 7, since it is not still investigated and examined by what distance each of the IO blocks of TYPE-B and TYPE-C should be spaced away from an IO block of TYPE-E, respective relationships between TYPE-B and TYPE-E and between TYPE-C and TYPE-E are represented by “−1”.

Furthermore, according to the present invention, a special layout rule for the layout of IO blocks on the chip surface 14a is previously prepared and stored as a two-dimensional table in the hard disk 28. Referring to FIG. 8, the special layout rule is conceptually shown by way of example. The special layout rule is used when two IO blocks are arranged to be adjacent to each other at any one of the four corner areas of the lattice L.

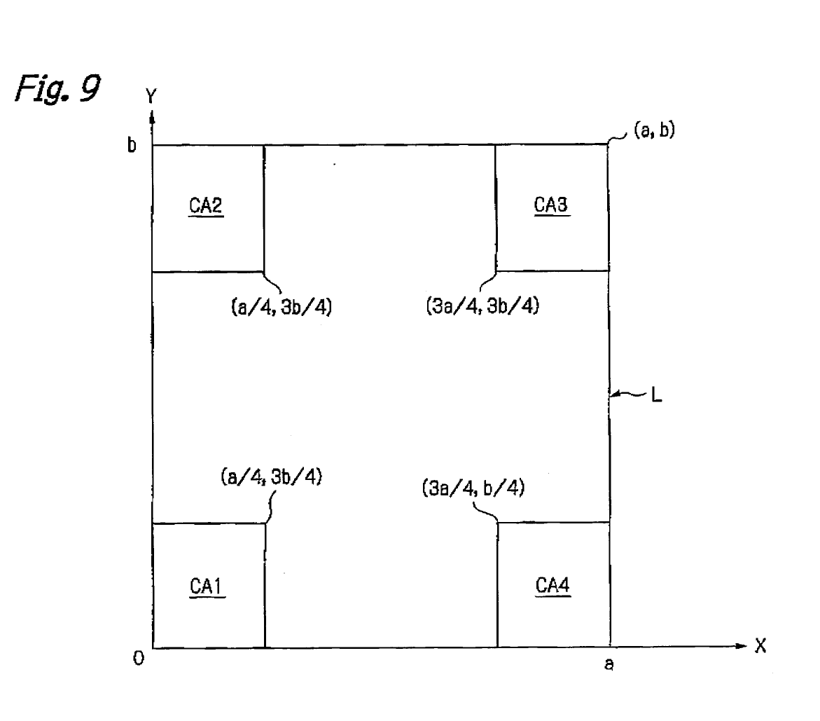

With reference to FIG. 9, a whole of the lattice L is illustrated, and has an a×b size. Also, as shown in FIG. 9, an X-Y coordinate system is defined with respect to the lattice L, and each of the four corner areas of the lattice L, indicated by references CA1, CA2, CA3, and CA4, is defined as a square having a/4×b/4 size. Namely, the corner area CA1 is defined by the four coordinates (0, 0), (0, b/4), (a/4, b/b), and (a/4, 0); the corner area CA2 is defined by the four coordinates (0, 3b/4), (0, b), (a/4, b), and (a/4, 3b/4); the corner area CA3 is defined by the four coordinates (3a/4, 3b/4), (3a/4, b), (a, b), and (a, 3b/4); and the corner area CA4 is defined by the four coordinates (3a/4, 0), (3a/4, b/4), (a, b/4), and (a, 0).

When two adjacent IO blocks are arranged such that both the center coordinates thereof fall in any one of the four corner areas CA1, CA2, CA3, and CA4 of the lattice L, the design requirements of the wiring-arrangement for the wiring-board 12 become severer, in comparison with the case where the two adjacent IO blocks are arranged at the other area of the lattice L except for the corner areas. Thus, each minimum permissible distance, as shown in the special layout rule of FIG. 8, is somewhat larger than a corresponding minimum permissible distance shown in FIG. 7.

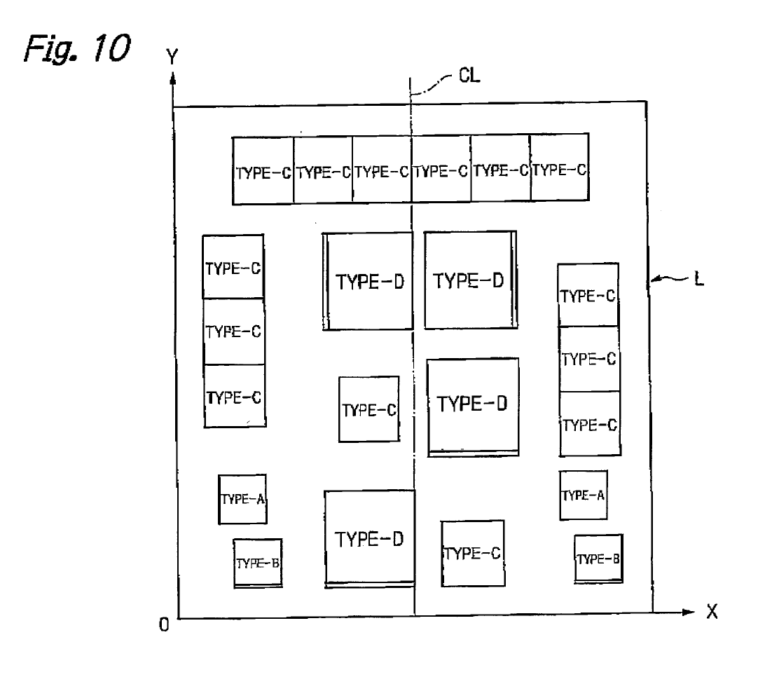

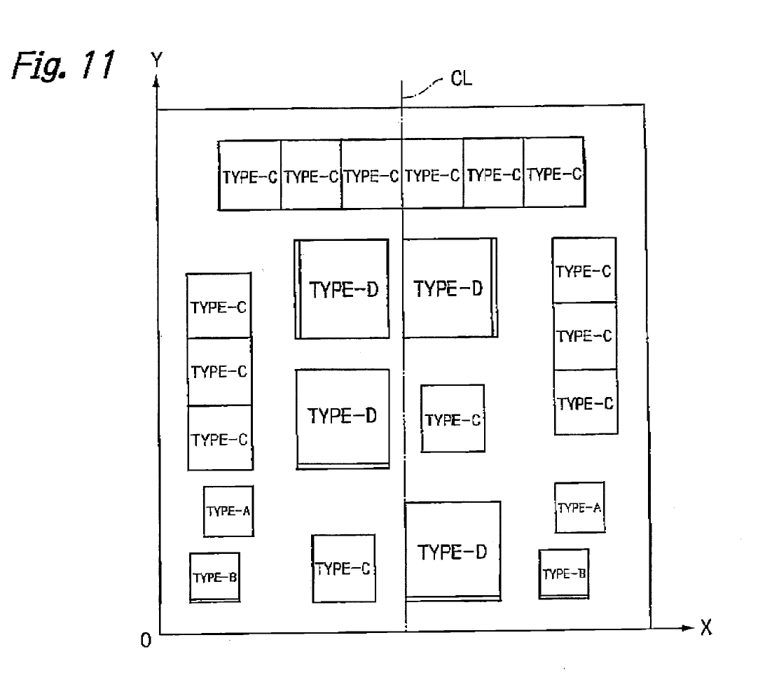

With respect to FIG. 10, a layout of IO blocks, which is properly defined and arranged on the chip surface 14a, is shown by way of example. After the proper completion of the layout of IO blocks on the chip surface 14a, a layout of IO blocks, corresponding to the layout of IO blocks on the chip surface 14a, is designed on the area of the upper surface of the wiring-board 12 on which the semiconductor chip 14 is to be mounted, but it is possible to easily perform the design of the layout of IO blocks on the wiring-board 12, because there is a mirror image relationship between the layout of IO blocks on the chip surface 14a and the layout of IO blocks on the wiring-board 12.

Namely, the layout of IO blocks on the wiring-board 14 can be immediately obtained by turning over the layout of IO blocks on the chip surface 14a around an axis which is parallel to either the X-axis or Y-axis of the X-Y coordinate system. For example, by turning over the layout of IO blocks around a center axis CL parallel to the Y-axis, the design of the layout of IO blocks on the chip surface 14a is immediately completed, as shown in FIG. 11. In short, although the layout of IO blocks, shown in FIG. 10, exists on the chip surface 14a of the semiconductor chip 14, the layout of IO blocks, shown in FIG. 11, exists on the area of the wiring-board 12 on which the semiconductor chip 14 should be mounted.

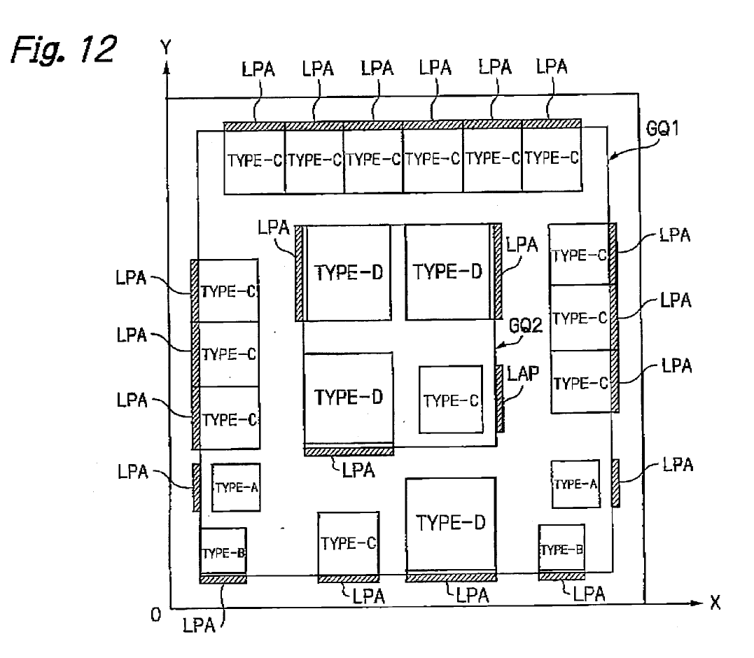

After the completion of the layout of IO blocks on the wiring-board 12, as shown in FIG. 12, a line-passage area LPA is defined with respect to each of the IO blocks on the wiring-board 12. Wiring-lines, which are drawn out from the S-pads of each IO block, pass through a corresponding line-passage area LPA. In FIG. 12, although each of the line-passage areas LPA is illustrated as a hatching area, in reality, it is displayed on the screen of the display unit 20 with a suitable single-color, for example, the same color (green) as the S-pads of each IO block.

For the definition of the line-passage areas LPA, a first geometrical quadrilateral GQ1 is produced on the screen of the display unit 20 such that the outer sides of the outermost IO blocks are tangential to a corresponding side of the first geometrical quadrilateral GQ1, as shown in FIG. 12. The line-passage area LPA of each outermost IO block is defined on and along a corresponding side of the first geometrical quadrilateral GQ1, and the definition of the line-passage areas LPA is automatically performed in accordance with a line-passage-area-definition algorithm, which is well known in this field, at the same time when the first geometrical quadrilateral GQl is produced.

In FIG. 12, although the two IO blocks of TYPE-A are not tangential to the first geometrical quadrilateral GQ1, each of these IO blocks are directly opposed to a corresponding side of the first geometrical quadrilateral GQ1 without being subjected to interference. In this case, the line-passage area for each IO block of TYPE-A is defined by suitably operating the mouse 24 on and along a corresponding side of the first geometrical quadrilateral GQ1 in accordance with the line-passage-area-definition algorithm.

When the IO blocks to which line-passage area should be defined still remain, a second geometrical quadrilateral GQ2 is produced on the screen of the display unit 20 such that the outer sides of the remaining outermost IO blocks are tangential to a corresponding side of the second geometrical quadrilateral GQ2, as shown in FIG. 12, the line-passage area of each remaining IO block is defined on and along a corresponding side of the second geometrical quadrilateral GQ2 in substantially the same manner as mentioned above.

In the example shown in FIG. 12, although it is possible to complete the definition of the line-passage areas for all the IO blocks by the production of the first and second geometrical quadrilaterals GQ1 and GQ2, a geometrical quadrilateral is further produced if IO blocks to which line-passage areas should be defined still remain.

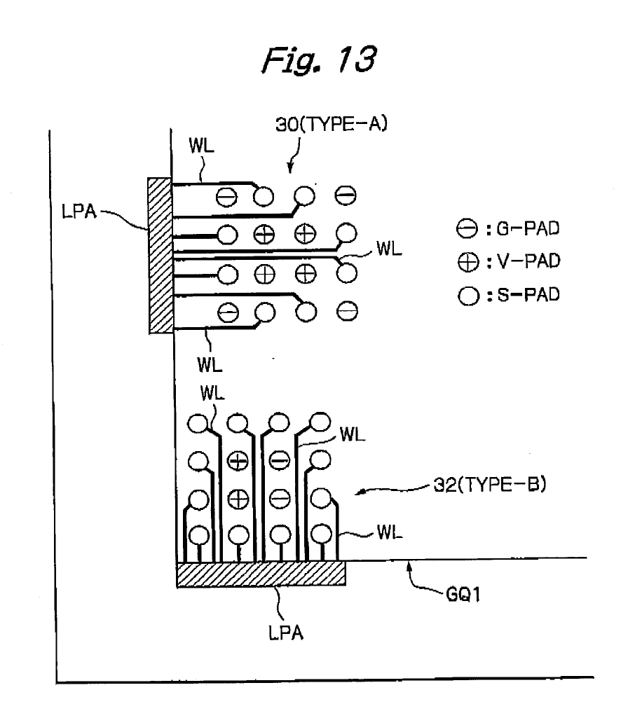

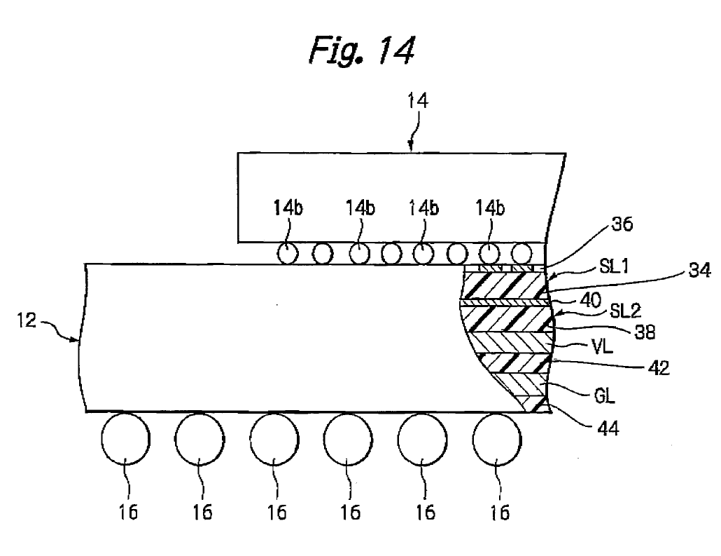

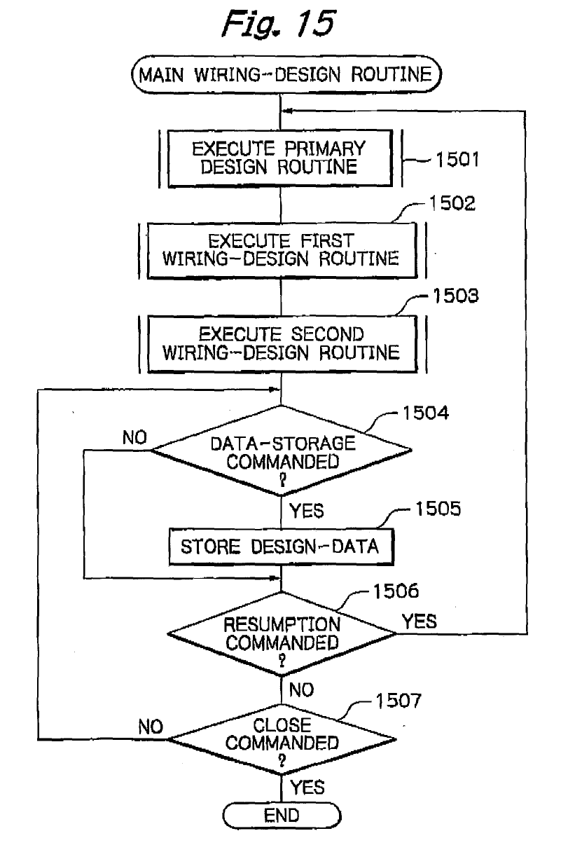

After the definition of the line-passage areas for all the IO blocks, as shown in FIG. 13 by way of example, wiring-lines WL are produced on the screen of the display unit 20 so as to be drawn out from the S-pads of each IO block to a corresponding line-passage area LPA, and it is possible to automatically perform the production of the wiring-lines WL in accordance with a wiring-line-production algorithm, which is well known in this field.

Also, after the definition of the line-passage areas LPA for all the IO blocks, a number of signal layers to be included in the wiring-board 12 is determined. Namely, the number of signal layers is equal to a number of geometrical quadrilaterals produced for defining the line-passage areas LPA for all the IO blocks.

Thus, as shown in FIG. 14, the wiring-board 12 includes a first signal layer SL1, and a second signal layer SL2, and the first signal layer SL1 is placed above the second signal layer SL2. The first signal layer SL1 includes an insulation layer 34, and a circuit pattern layer 36 formed thereon, and the G-pads, V-pads, and S-pads of all the IO blocks are in the circuit pattern layer 36. Similarly, the second signal layer SL2 includes an insulation layer 38, and a circuit pattern layer 40.

In FIG. 14, the power source layer and the ground layer are indicated by reference VL and GL, respectively. The power source layer VL is placed beneath the second signal layer SL2, and an insulation layer 42 is intervened between the power source layer VL and the ground layer GL. The wiring-board includes an insulation layer 44 placed beneath the ground layer GL, and an array of pads are formed and arranged on a bottom surface of the insulation layer 44, with the respective solder balls 16 being adhered to the pads.

The respective wiring-lines WL, which pass through the line-passage areas LPA defined on the sides of the first geometrical quadrilateral GQ1, are electrically connected to the circuit pattern layer 36 of the first signal layer SL1, and are then electrically connected to corresponding solder balls 16 via through-holes formed in the layers SL2, 38, VL, 42, GL, and 44. Also, The respective wiring-lines WL, which pass through the line-passage areas LPA defined on the sides of the second geometrical quadrilateral GQ2, are electrically connected to the circuit pattern layer 40 of the second signal layer SL2 via through-holes formed in the first signal layer SL1, and are then electrically connected to corresponding solder balls 16 via through-holes formed in the layers 38, VL, 42, GL, and

Note that it is possible to perform the wiring-arrangement between the line-passage areas LPA and the array of solder balls 16, using a well-known two-dimensional-wiring algorithm, due to the multi-signal layer structure of the wiring-board 12.

FIG. 15 shows a flowchart of a main wiring-design routine for designing a wiring-arrangement for the wiring-board 12.

At step 1501, a primary design routine is executed, whereby a layout of various IO blocks is designed on an area of the wiring-board 12 on which the FC semiconductor chip 14 is to be mounted Also, at step 1501, a line-passage area LPA is defined with respect to each IO block.

At step 1502, a first wiring-design routine is executed to thereby establish wiring-arrangements between the IO blocks and the line-passage areas. Then, at step 1503, a second wiring design routine is executed to thereby establish wiring-arrangements between the line-passage areas and the array of solder balls. Note, it is possible to perform a design of these wiring-arrangements performed in accordance with a suitable wiring algorithm, which is well known in this field.

At step 1504, it is monitored whether a data-storage command is input to the system control unit 18 by operating either a given key on the keyboard 22 or the mouse 24. When the input of the data-storage command is confirmed, the control proceeds to step 1505, in which the wiring-design data, obtained in steps 1501, 1502, and 1503, is stored in the hard disk 28.

At step 1504, when the input of the data-storage command is not confirmed, the control proceeds to step 1506, in which it is monitored whether a resumption command is input to the system control unit 18 by operating either a given key on the keyboard 22 or the mouse 24. When the input of the resumption command is confirmed, the control returns to step 1501, and thus the design routines are again executed.

At step 1506, when the input of the resumption command is not confirmed, the control proceeds to step 1507, in which it is monitored whether a close command is input to the system control unit 18 by operating either a given key on the keyboard 22 or the mouse 24. When the input of the close command is not confirmed, the control returns to step 1504. When the input of the close command is confirmed, the main wiring-design routine ends.

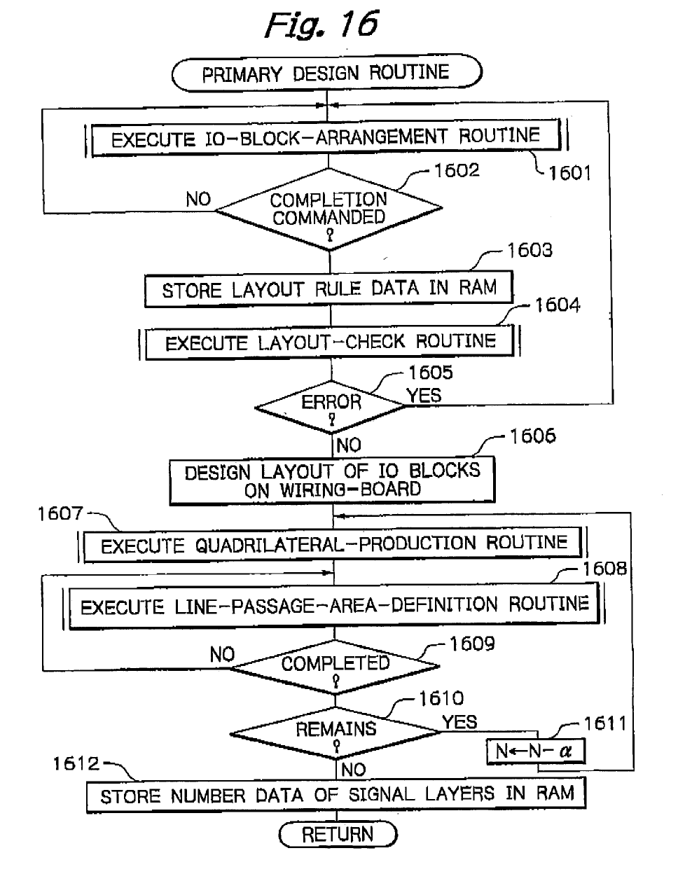

FIG. 16 shows a flowchart of the primary design routine executed in step 1501 of FIG. 16.

At step 1601, an IO-block-arrangement routine is executed, whereby various IO blocks are arranged on the lattice L, displayed on the screen of the display unit 20, by operating the keyboard 22 and the mouse 24, as explained with reference to FIGS. 3 to 6.

At step 1602, it is monitored whether a completion command is input to the system control unit 18 by operating either a given key on the keyboard 22 or the mouse 24. The input of the completion command is performed by an operator after a layout of IO blocks on the lattice L is completed. When the input of the completion command is not confirmed, the control returns to step 1601.

At step 1602, when the input of the completion command is confirmed, the control proceeds to step 1603, in which the general layout rule table (FIG. 7) and the special layout table (FIG. 8) are read from the hard disk 28, and are then stored in the random-access memory (RAM) of the system control unit 18.

At step 1604, a layout-check routine is executed, whereby it is checked whether or not the layout of IO blocks is properly designed on the lattice L based on the general and special layout rule data. Then, at step 1605, it is determined whether or not an error exists in the layout of IO blocks. When the existence of error is confirmed, the control returns to step 1601 to thereby eliminate the error from the layout of IO blocks.

At step 1605, when the existence of error is not confirmed, the control proceeds to step 1606, in which a layout of IO block is designed on an area of the wiring-board on which the FC semiconductor chip 14 is to be mounted. As already stated, it is possible to easily perform the design of the layout of IO blocks on the wiring-board 14 by turning over the checked layout of IO blocks on the chip surface 14a around the center axis CL parallel to the Y-axis X-Y coordinate system (FIGS. 10 and 11).

After the design of the layout of IO blocks on the wiring-board 12 is completed, the control proceeds to step 1607, in which a quadrilateral-production routine is executed to thereby produce a geometrical quadrilateral, as explained with reference to FIG. 12.

At step 1608, a line-passage-area-definition routine is executed to thereby define line-passage areas LPA on and along the sides of the geometrical quadrilateral in the manner stated with reference to FIG. 12. Namely, the definition of the line-passage areas LPA is automatically performed with respect the IO blocks which are tangential to any one of the sides of the geometrical quadrilateral. Also, when there is an IO block which is directly opposed to any one of the sides of the geometrical quadrilateral without being tangential thereto, a line-passage area LPA for the IO block concerned is defined by suitably operating the mouse 24 on and along the corresponding side of the geometrical quadrilateral.

At step 1609, it is monitored whether the definition of the line-passages LPA is completed with respect to all the IO blocks involved with the geometrical quadrilateral. When the definition of all the line-passages LPA is not still completed, the control returns to step 1608.

At step 1610, it is determined whether the IO blocks to which line-passage areas should be defined 1, still remain. When the existence of the remaining IO blocks is confirmed, the control returns to step 1611, in which the following calculation is executed:

N←N−α

herein: N is a total number of the IO blocks arranged on the lattice L; and α is a number of the IO blocks involved with the geometrical quadrilateral. Thus, (N−α) is equivalent to a number of the remaining IO blocks to which the line-passage areas LPA should be defined.

After the calculation is completed at step 1611, the control returns to step 1607, whereby another geometrical quadrilateral is produced with respect to the remaining IO blocks for the definition of the line-passage areas LPA.

At step 1610, when no IO blocks to which a line-passage area should be defined remain, the control proceeds to step 1612, in which a number of the produced geometrical quadrilaterals is stored in the RAM of the system control unit 18 as number data of signal layers to be included in the wiring-board 12.

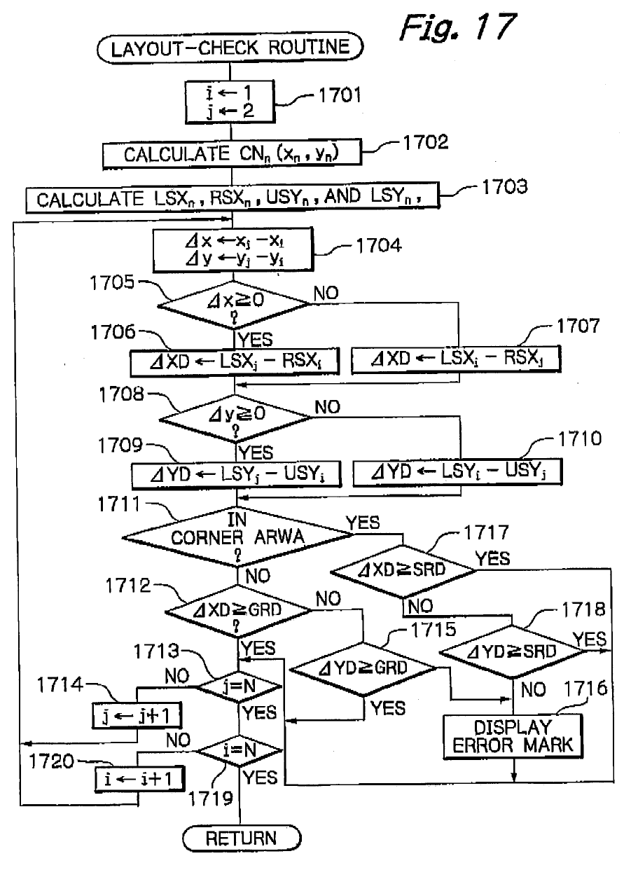

FIG. 17 shows a flowchart of the layout-check routine executed in step 1604 of the primary design routine of FIG. 16.

At step 1701, a counter i is initialized to “1”, and a counter j is initialized to “2”. At step 1702, in order to identify positions of all the IO blocks arranged on the lattice L (FIG. 10), a center position CNₙ(xₙ, yₙ) of each IO block is calculated with respect to the X-Y coordinate system. Then, at step 1703, two X-coordinate components LSXₙ and RSXₙ and two Y-coordinate components USYₙ and LSYₙ for identifying positions of the four sides of each IO block are calculated. Namely, the respective left, right, upper, and lower sides of each IO block are represented by the X-coordinate components LSXₙ and RSXₙ, and Y-coordinate components USYₙ and LSYₙ.

At step 1704, the following calculations is executed:

Δx←xⱼ−xᵢ

Δy←yⱼ−yᵢ

At step 1705, it is determined whether the calculated result Δx is equal to or larger than “0”.

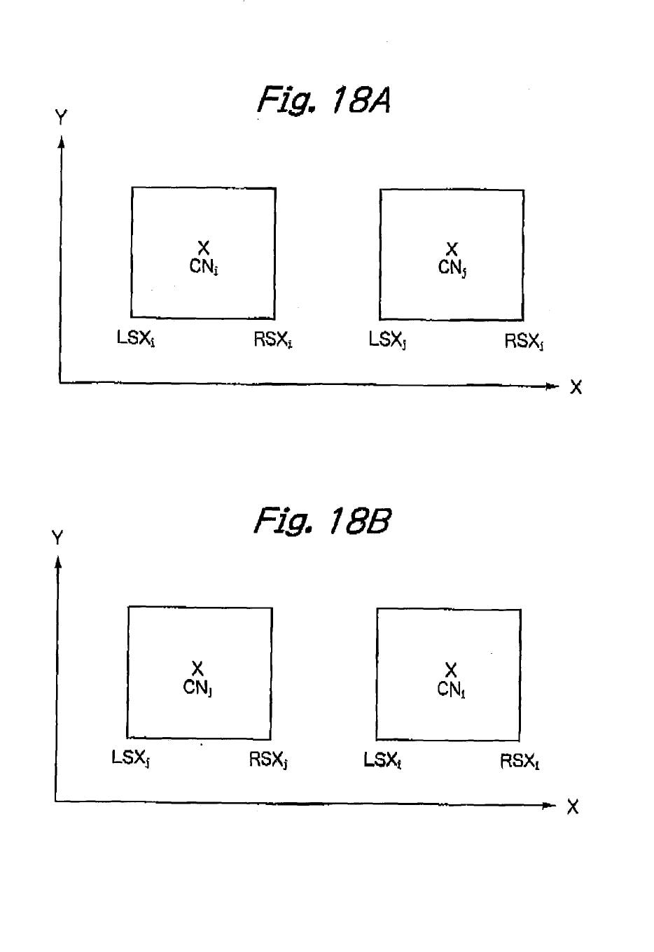

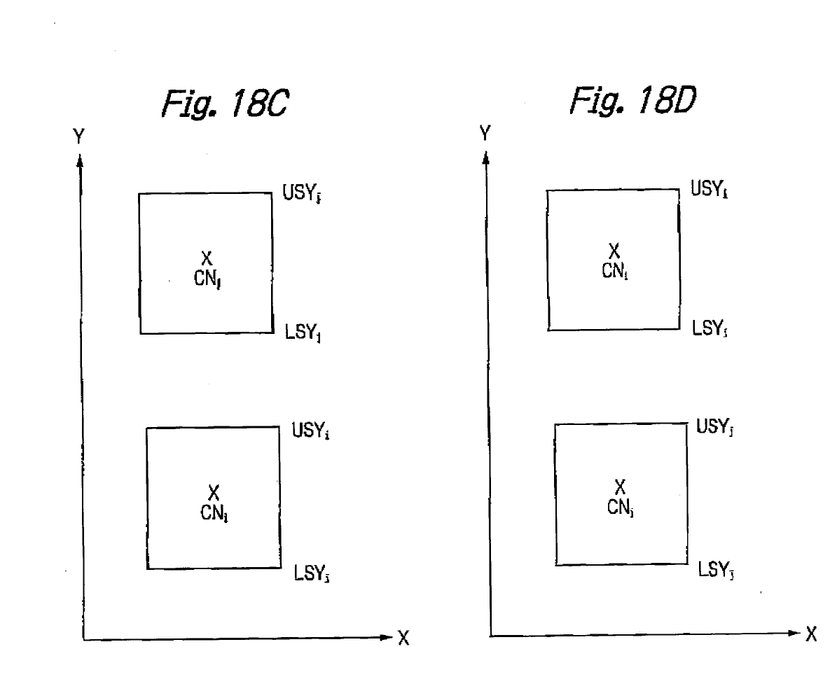

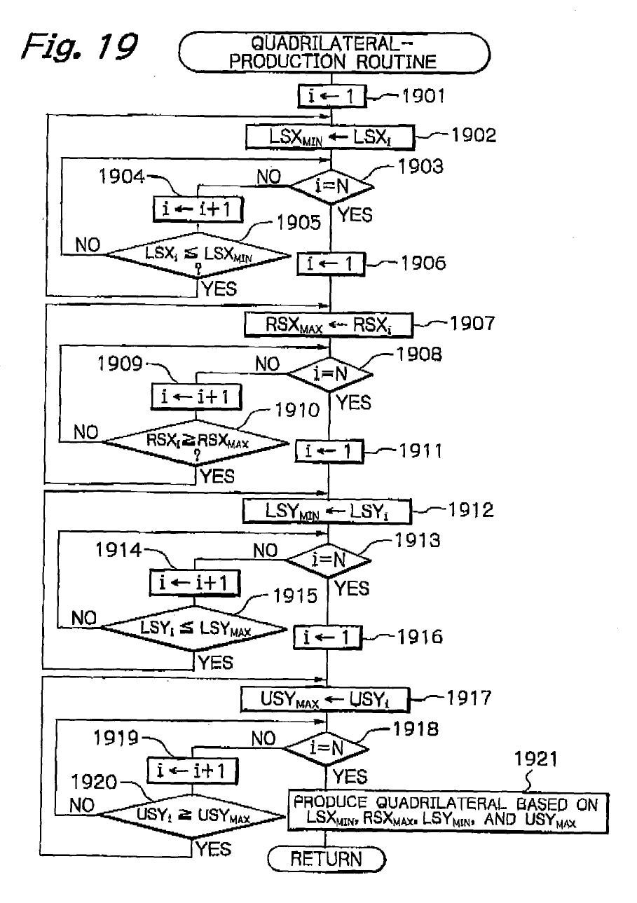

If Δx≧0, i.e., if the two IO blocks, identified by the center positions CNₗ and CNⱼ, are arranged in a relative positional relationship as representatively shown in FIG. 18A, the control proceeds to step 1706, in which the following calculation is executed:

ΔXD←LSXⱼ−RSXᵢ

At step 1705, if Δx<0, i.e., if the two IO blocks, identified by the center positions CNᵢ and CNⱼ, are arranged in a relative positional relationship as representatively shown in FIG. 18B, the control proceeds to step 1707, in which the following calculation is executed:

ΔXD←LSXᵢ−RSXⱼ

In either case, the control proceeds to step 1708, in which it is determined whether the calculated result Δy is equal to or larger than “0”.

If Δy≧0, i.e., if the two IO blocks, identified by the center positions CNᵢ and CNⱼ, are arranged in a relative positional relationship as representatively shown in FIG. 18C, the control proceeds to step 1709, in which the following calculation is executed:

ΔYD←LSYⱼ−USYᵢ

At step 1705, if Δy<0, i.e., if the two IO blocks, identified by the center positions CNₗ and CNⱼ, are arranged in a relative positional relationship as representatively shown in FIG. 18D, the control proceeds to step 1710, in which the following calculation is executed:

ΔYD←LSYᵢ−USYⱼ

In either case, at step 1711, it is determined whether both the center positions CNᵢ and CNⱼ of the two IO blocks fall in one of the corner areas CA1, CA2, CA3, and CA4 of the lattice L (FIG. 9).

When it is confirmed that both the center positions CNₗ and CNⱼ do not fall in any one of the corner areas CA1, CA2, CA3, and CA4 of the lattice L, the control proceeds to step 1712, in which it is determined whether the calculated result ΔXD is equal to or larger than numerical data GRD, representing a minimum permissible distance, selected from the general layout rule table (FIG. 7) based on the relationship between the two IO blocks (CNᵢ and CNⱼ).

If ΔXD≧GRD, i.e., if the two IO blocks (CNᵢ and CNⱼ) are properly spaced away from each other along the X-axis, the control proceeds to step 1713, in which it is monitored whether a count number of the counter j has reached N. When the count number of the counter j has not reached N, the control proceeds step 1714, in which the count number of the counter j is incremented by “1”. Then, the control returns to step 1704.

At step 1712, if ΔXD<GRD, i.e., if the two IO blocks (CNₗ and CNⱼ) are improperly spaced away from each other along the X-axis, the control proceeds to step 1715, in which it is determined whether the calculated result ΔYD (step 1709 or 1710) is equal to or larger than the numerical data GRD.

If ΔYD≧GRD, i.e., if the two IO blocks (CNᵢ and CNⱼ) are properly spaced away from each other along the Y-axis, the relative positional relationship between the two IO blocks (CNᵢ and CNⱼ) is permissible, and thus the control proceeds to step 1713.

At step 1715, if ΔYD<GRD, i.e., if it is determined that the two IO blocks (CNᵢ and CNⱼ) are improperly spaced away from each other along both the X-axis and the Y-axis, the control proceeds to step 1716, in which an error mark is displayed on the screen of the display unit 20 such that the improper IO blocks (CNᵢ and CNⱼ) can be easily recognized by an operator. For example, the improper IO blocks may be marked with a cross “X”.

At step 1711, when both the center positions CNᵢ and CNⱼ of the two IO blocks fall in one of the corner areas CA1, CA2, CA3, and CA4 of the lattice L (FIG. 9), the control proceeds to step 1717, in which it is determined whether the calculated result ΔYD is equal to or larger than numerical data SRD, representing a minimum permissible distance, selected from the special layout rule table (FIG. 8) based on the relationship between the two IO blocks (CNᵢ and CNⱼ).

If ΔYD≧SRD, i.e., if the two IO blocks (CNᵢ and CNⱼ) are properly spaced away from each other along the X-axis, the control proceeds to step 1713. On the other hand, if ΔXD<SRD, i.e., if the two IO blocks (CNᵢ and CNⱼ) are improperly spaced away from each other along the X-axis, the control proceeds to step 1718, in which it is determined whether the calculated result ΔYD (step 1709 or 1710) is equal to or larger than the numerical data SRD.

If ΔYD≧SRD, i.e., if the two IO blocks (CNᵢ and CNⱼ) are properly spaced away from each other along the Y-axis, the relative positional relationship between the two IO blocks (CNᵢ and CNⱼ) is permissible, and thus the control proceeds to step 1713.

At step 1718, if ΔYD<RD, i.e., if it is determined that the two IO blocks (CNᵢ and CNⱼ) are improperly spaced away from each other along both the X-axis and the Y-axis, the control proceeds to step 1716, in which an error mark is displayed on the screen of the display unit 20 such that the improper IO blocks (CNᵢ and CNⱼ) can be easily recognized by an operator.

At step 1713, when the count number of the counter j has reached N, the control proceeds to step 1719, in which it is monitored whether a count number of the counter i has reached N. When the count number of the counter i has not reached N, the control proceeds step 1720, in which the count number of the counter i is incremented by “1”, and then the control returns to step 1704.

Accordingly, when the count number of the counter i has reached N, the check of the layout of IO blocks on the lattice L is completed.

FIG. 19 shows a flowchart of the quadrilateral-production routine executed in step 1607 of the primary design routine of FIG. 16.

At step 1901, a count number of a counter i is initialized to “1”, and, at step 1902, the X-coordinate component LSXᵢ, representing the left side of the IO block (CNᵢ), is provisionally made to be a minimum value LSX_{MIN}.

At step 1903, it is monitored whether the count number of the counter i has reached N. If i<N, the control proceeds to step 1904, in which the count number of the counter i is incremented by “1”. Then, at step 1905, it is determined whether the X-coordinate component LSXᵢ is equal to or larger than the minimum value LSX_{MIN}.

If LSXᵢ≦LSX_{MIN}, the control returns to step 1902, in which the X-coordinate component LSXᵢ is made to be the minimum value LSX_{MIN}. On the other hand, if LSXᵢ>LSX_{MIN}, the control returns to step 1903. Thus, at step 1903, when the count number of the counter i has reached N, the actual minimum value LSX_{MIN} is settled.

At step 1906, the count number of the counter i is again initialized to “1”, and, at step 1907, the X-coordinate component RSXᵢ, representing the right side of the IO block (CNᵢ), is provisionally made to be a maximum value RSX_{MAX}.

At step 1908, it is monitored whether the count number of the counter i has reached N. If i<N, the control proceeds to step 1909, in which the count number of the counter i is incremented by “1”. Then, at step 1910, it is determined whether the X-coordinate component RSXᵢ is equal to or larger than the maximum value RSX_{MAX}.

If RSXᵢ≧RSX_{MAX}, the control returns to step 1907, in which the X-coordinate component RSXᵢ is made to be the maximum value RSX_{MAX}. On the other hand, if RSXᵢ<RSX_{MAX}, the control returns to step 1908. Thus, at step 1908, when the count number of the counter i has reached N, the actual maximum value RSX_{MAX} is settled.

At step 1911, the count number of the counter i is also initialized to “1”, and, at step 1912, the Y-coordinate component LSYᵢ, representing the lower side of the IO block (CNᵢ), is provisionally made to be a minimum value LSY_{MIN}.

At step 1913, it is monitored whether the count in number of the counter i has reached N. If i<N, the control proceeds to step 1914, in which the count number of the counter i is incremented by “1”. Then, at step 1915, it is determined whether the Y-coordinate component LSYᵢ is equal to or larger than the minimum value LSY_{MIN}.

If LSYᵢ≦LSY_{MIN}, the control returns to step 1912, in which the Y-coordinate component LSYᵢ is made to be the minimum value LSY_{MIN}. On the other hand, if LSYᵢ>LSY_{MIN}, the control returns to step 1913. Thus, at step 1913, when the count number of the counter i has reached N, the actual minimum value LSY_{MIN} is settled.

At step 1916, the count number of the counter i is further initialized to “1”, and, at step 1917, the Y-coordinate component USYᵢ, representing the upper side of the IO block (CNₗ), is provisionally made to be a maximum value USY_{MAX}.

At step 1918, it is monitored whether the count number of the counter i has reached N. If i<N, the control proceeds to step 1919, in which the count number of the counter i is incremented by “1”. Then, at step 1920, it is determined whether the Y-coordinate component USYᵢ is equal to or larger than the maximum value USY_{MAX}.

If USYᵢ≧USY_{MAX}, the control returns to step 1918, in which the Y-coordinate component USYᵢ is made to be the maximum value USY_{MAX}. On the other hand, if USYᵢ<USY_{MAX}, the control returns to step 1918. Thus, at step 1918, when the count number of the counter i has reached N, the actual maximum value USY_{MAX} is settled.

At step 1921, a geometrical quadrilateral is produced and displayed on the screen of the display unit 20 on the basis of the LSX_{MIN}, RSX_{MAX}, LSY_{MIN}, and USY_{MAX}. Namely, the respective left, right, lower, and upper sides of the geometrical quadrilateral have the X-coordinate component LSX_{MIN}, X-coordinate component RSX_{MAX}, Y-coordinate component LSY_{MIN}, and X-coordinate component USY_{MAX}.

Finally, it will be understood by those skilled in the art that the foregoing description is of preferred embodiments of the product, and that various changes and modifications may be made to the present invention without departing from the spirit and scope thereof.

1. A wiring-design system for designing a wiring-arrangement for a wiring-board on which an area-input/output type semiconductor chip is mounted, which system comprises;
a display unit that displays a lattice representing an array of pads to be provided on a chip surface of said semiconductor chip;
a first layout design system that defines and arranges various IO blocks on said lattice to thereby design a first layout of IO blocks thereon;
a check system that checks whether or not said first layout of IO blocks is properly performed in accordance with a previously-prepared layout rule;
a second layout design system that designs a second layout of IO block to be provided on said wiring-board, based on said first layout of IO blocks on said lattice, when it is confirmed by said check system that said first layout of IO blocks is properly performed; and
a wiring-arrangement production system that produces a wiring-arrangement of said wiring-board with respect to said second layout of IO blocks.

2. A wiring-design system as set forth in claim 1, wherein each of said IO blocks is composed of ground pads to be connected to a ground layer of said wiring-board, electric power pads to be connected an electric power layer of said wiring board, and signal pads to be connected to a signal layer of said wiring-board.

3. A wiring-design system as set forth in claim 2, wherein said second layout design system includes a line-passage-area-definition system that defines line-passage areas with respect to each of said IO blocks on said wiring-board, with wiring-lines drawn out from the signal pads of each IO block passing through a corresponding line passage area.

4. A wiring-design system as set forth in claim 3, wherein said second layout design system further includes a geometrical-quadrilateral production system that produces a geometrical quadrilateral on said second layout of IO blocks such that the sides of said of geometrical quadrilateral are tangential to outer sides of the outermost IO blocks, and said geometrical-quadrilateral production system cooperates with said line-passage-area-definition system such that each line-passage area is defined and produced on and along a corresponding side of said geometrical quadrilateral.

5. A wiring-design system as set forth in claim 4, wherein said geometrical-quadrilateral production system produces another geometrical quadrilateral when there are remaining IO blocks provided inside said outermost IO, the production of said other geometrical quadrilateral is performed such that the sides of said other geometrical quadrilateral are tangential to outer sides of the remaining IO blocks, and said geometrical-quadrilateral production system cooperates with said line-passage-area-definition system such that each line-passage area is defined and produced on and along a corresponding side of said other geometrical quadrilateral.

6. A wiring-design system as set forth in claim 5, wherein the signal layer of said wiring-board is formed as a multi-layer structure including signal layers, a number of which corresponds to a number of said geometrical quadrilaterals, and the wiring-lines, passing through the line-passage area involved with the outermost geometrical quadrilateral are connected to the uppermost signal layer.

7. A wiring-design system as set forth in claim 1, wherein said previously-prepared layout rule comprises at least two types of layout rules, and said check system selects one of said at least two types of layout rules in accordance with design requirements of the wiring-arrangement for said wiring-board.

8. A wiring design system as set forth in claim 1, wherein said previously-prepared layout rule comprises at least two types of layout rules, one of said at least two types of layout rules being severer than the other type of layout rule, and said check system includes a determination system that determines whether two adjacent IO blocks are arranged in any one of corner areas of said lattice, and checks whether said two adjacent IO blocks are properly arranged in accordance with said one type of layout rule.
